(19) United States
(12) Patent Application Publication
(10) Pub. No.: US 2024/0283216 A1
(43) Pub. Date: Aug. 22, 2024

(54) SUBCARRIER WAFER, SUBCARRIER, METHOD FOR MANUFACTURING SUBCARRIER WAFER

(71) Applicant: TDK CORPORATION, Tokyo (JP)

(72) Inventors: Takashi HONDA, Tokyo (JP); Takashi AOYAGI, Tokyo (JP); Makoto FUKUDA, Tokyo (JP); Tsuyoshi KOMAKI, Tokyo (JP); Ryohei FUKUZAKI, Hong Kong (CN)

(73) Assignee: TDK CORPORATION, Tokyo (JP)

(21) Appl. No.: 18/524,024

(22) Filed: Nov. 30, 2023

(30) Foreign Application Priority Data
Feb. 17, 2023 (JP) 2023-023737

(51) Int. Cl. H01S 5/02315; H01S 5/02

(52) U.S. Cl. CPC H01S 5/02315; H01S 5/0201

(57) ABSTRACT

What is provided is a subcarrier wafer in which chipping, particles, cracking, and the like are curbed.

This subcarrier wafer is a subcarrier wafer for a laser module including a wafer, and a plurality of protective layers that are provided on a main surface of the wafer. The plurality of protective layers are arrayed separately, and a part on the main surface of the wafer is exposed.

### BACKGROUND OF THE INVENTION

### Field of the Invention

The present invention relates to a subcarrier wafer, a subcarrier, and a method for manufacturing a subcarrier wafer.

### Description of Related Art

With increases in data traffic, optical communication systems and various optical devices around us using an optical communication system are becoming multifunctional. Recently, multifunctional and compact optical devices have been studied due to the demand for multifunctional and high-density devices.

In recent years, a technology of silicon photonics, in which a light emitting element and a light receiving element are integrated in a silicon waveguide, has progressed and is being used in optical communication systems. Planar lightwave circuits (PLC) performing optical signal processing such as multiplexing, demultiplexing, and wavelength selection are one example of typical silicon waveguides used in optical communication systems (for example, Patent Document 1).

In addition to optical communication systems, for example, regarding wearable devices, small-sized projectors, and the like around us as well, there is a demand for multifunctional and compact optical devices that exhibit a plurality of functions in accordance with the purpose of use and can be carried around in their entirety.

XR glasses such as augmented reality (AR) glasses and virtual reality (VR) glasses are expected to be compact wearable devices. Regarding wearable devices such as AR glasses and VR glasses, the key to popularization thereof is miniaturization to the extent that they are equipped with every function in an ordinary size of eyeglasses.

AR glasses, VR glasses, and the like provided with laser diodes on subcarriers are known. A subcarrier is a member in which a protective layer or the like constituted using Si oxide or Si nitride is formed on a Si wafer. In Patent Document 1, a wafer having various kinds of members formed thereon and cut into chips is used. A wafer is cut into chips by blade dicing or stealth dicing using a laser.

### PATENT DOCUMENT

[Patent Document 1] Japanese Unexamined Patent Application, First Publication No. 2016-001289

### SUMMARY OF THE INVENTION

Here, a protective layer is constituted using a material harder than that of a wafer, and when blade dicing is performed with respect to a wafer having a protective layer formed thereon, chipping or particles may occur in a part with which a cutting blade comes into contact. In addition, when stealth dicing is performed with respect to a wafer having a protective layer formed thereon, chipping or cracking may occur due to a difference in adhesion between a wafer and a protective layer during expansion for singulation. As described above, it is difficult to provide a subcarrier wafer free from chipping, particles, cracking, and the like with a technology in the related art.

The present invention has been made in consideration of the foregoing circumstances, and an object thereof is to provide a subcarrier wafer, a subcarrier, and a method for manufacturing a subcarrier wafer, in which occurrence of chipping, particles, cracking, and the like is curbed.

In order to resolve the foregoing problems, the present invention provides the following means.

(1) A subcarrier wafer according to an aspect of the present invention is a subcarrier wafer for a laser module including a wafer, and a plurality of protective layers that are provided on a main surface of the wafer. The plurality of protective layers are arrayed separately, and a part on the main surface of the wafer is exposed.

(2) In the subcarrier wafer according to the foregoing (1), side surfaces of the protective layers may have a tapered shape, and a distance between adjacent protective layers of the plurality of protective layers may increase away from the main surface of the wafer.

(3) In the subcarrier wafer according to the foregoing (1) or (2), a recessed portion which is recessed compared to a region overlapping the protective layers may be formed in a region not overlapping the protective layers in the wafer.

(4) In the subcarrier wafer according to the foregoing (1) to (3), the wafer may include Si as a main component, and the protective layers may include one selected from the group consisting of Si oxide, Si nitride, and a TEOS film as a main component.

(5) In the subcarrier wafer according to the foregoing (1) to (4), a distance between adjacent protective layers of the plurality of protective layers may be 10 μm or longer.

(6) A subcarrier according to another aspect of the present invention is a subcarrier for a laser module including a base, and a protective layer that is provided on a main surface of the base. A side surface of the protective layer has a tapered shape, and area of the protective layer in a planar view decreases away from the base.

(7) A method for manufacturing a subcarrier wafer according to another aspect of the present invention has a surface processing step of etching a wafer having a protective layer formed on a main surface thereof and defining a plurality of protective layers by exposing a part of a region in the wafer.

According to the present invention, it is possible to provide a subcarrier wafer, a subcarrier, and a method for manufacturing a subcarrier wafer, in which occurrence of chipping, particles, cracking, and the like is curbed.

### BRIEF DESCRIPTION OF THE DRAWINGS

FIG. 1 is a perspective view illustrating an example of a constitution of a subcarrier wafer according to an embodiment of the present invention.

FIG. 2 is a cross-sectional view of the subcarrier wafer in FIG. 1 along arrow line II-II.

FIG. 3 is a flowchart of a method for manufacturing a subcarrier according to the embodiment of the present invention.

FIG. 4 is an explanatory conceptual view of a form of a dicing step in FIG. 3.

FIG. 5 is an explanatory conceptual view of a form of the dicing step in FIG. 3 and is a view illustrating a modification example in FIG. 4.

FIG. 6 is a flowchart of the method for manufacturing a subcarrier according to a modification example in FIG. 3.

FIG. 7 is a perspective view illustrating an example of a constitution of a laser module according to the embodiment of the present invention.

FIG. 8 is a cross-sectional view of an incidence surface of a PLC of the laser module in FIG. 7.

FIG. 9 is a plan view of a part of the laser module in FIG. 7.

FIG. 10 is a cross-sectional view of the laser module in FIG. 7 along arrow line X-X.

FIG. 11 is explanatory cross-sectional view of an example of a method for manufacturing the laser module in FIG. 7.

FIG. 12 is a plan view of a packaged laser module.

FIG. 13 is a cross-sectional view of the laser module in FIG. 12.

FIG. 14 is a plan view of a state in which a cover of the laser module in FIG. 12 is removed.

FIG. 15 is a side view of the laser module in FIG. 12 viewed from an emission portion side.

FIG. 16 is a perspective view illustrating a form when the laser module in FIG. 12 is in use.

FIG. 17 is an explanatory conceptual view of XR glasses according to the embodiment of the present invention.

FIG. 18 is a conceptual view illustrating a condition in which an image is directly projected onto the retina by laser light emitted from the laser module according to the embodiment of the present invention.

### DETAILED DESCRIPTION OF THE INVENTION

Hereinafter, an embodiment will be described in detail suitably with reference to the drawings. In drawings used in the following description, in order to make characteristics easy to understand, characteristic portions may be illustrated in an enlarged manner for the sake of convenience, and dimensional ratios or the like of each constituent element may differ from actual values thereof. Materials, dimensions, and the like illustrated in the following description are merely exemplary examples. The present invention is not limited thereto and can be suitably changed and performed within a range in which the effects of the present invention are exhibited.

### [Subcarrier Wafer]

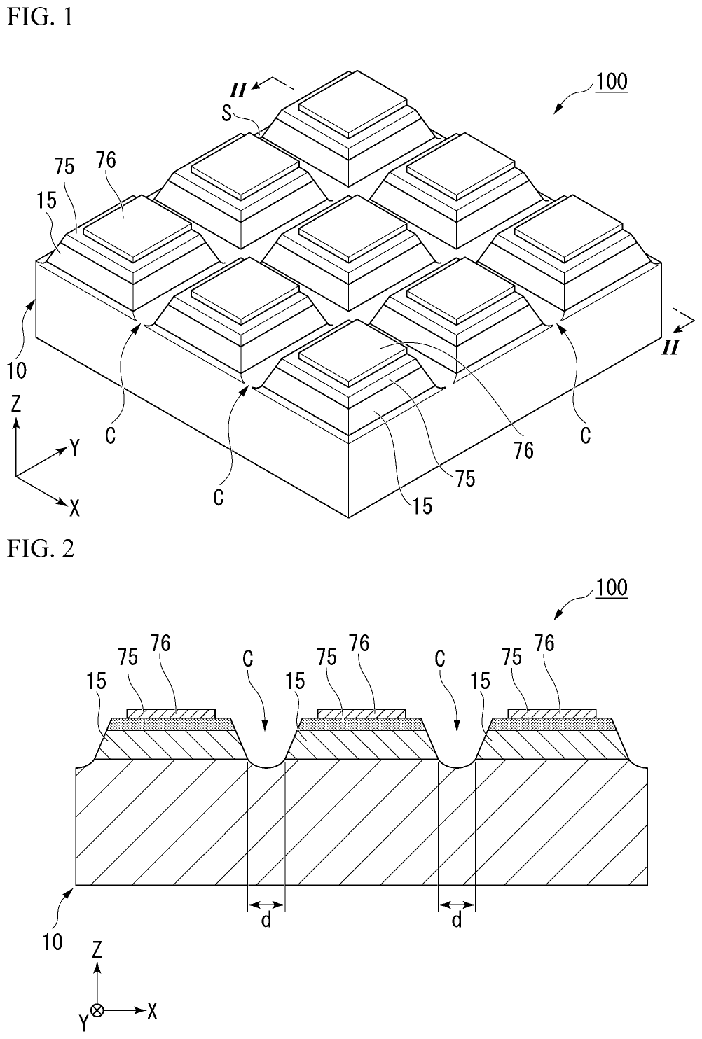

FIG. 1 is a perspective view illustrating an example of a constitution of a subcarrier wafer according to an embodiment of the present invention. FIG. 2 is a cross-sectional view of the subcarrier wafer in FIG. 1 along arrow line II-II. In FIGS. 1 and 2, for the sake of description, a part of the subcarrier wafer is illustrated in an enlarged manner. A subcarrier wafer 100 illustrated in FIGS. 1 and 2 is a subcarrier wafer for a laser module including a wafer 10, and a plurality of protective layers 15 that are provided on a main surface S of the wafer 10. The plurality of protective layers 15 are arrayed separately, and a part on the main surface S of the wafer 10 is exposed. As will be described below in detail, for example, the plurality of protective layers 15 are arrayed in a matrix shape.

For example, the wafer 10 includes Si as a main component. For example, the protective layers 15 include one selected from the group consisting of a Si oxide film, a thermal Si oxide film, Si nitride, and tetraethyl orthosilicate tetraethoxysilane (TEOS) as a main component. That is, the wafer 10 is a Si wafer, and for example, the protective layers 15 are any of layers constituted of SiOₓ, layers constituted of SiNₓ, and layers constituted of TEOS.

The subcarrier wafers 100 are diced and become predetermined chips (subcarriers). For example, the number of protective layers 15 provided in the subcarrier wafer 100 is the same as the number of subcarriers produced from the subcarrier wafer 100 via latter steps. For example, in the subcarrier wafer 100, a first metal layer 75 and a second metal layer 76 are formed on the protective layers 15.

Thicknesses of the protective layers 15 are 0.03 μm to 5 μm, for example, and are preferably 0.2 μm to 2 μm.

In the subcarrier wafer 100, for example, the plurality of protective layers 15 are arrayed in a matrix shape in a plan view in a laminating direction. In the example illustrated in FIGS. 1 and 2, the plurality of protective layers 15 are arranged in an X direction and a Y direction and are separated from each other in the X direction and the Y direction. It is preferable that the plurality of protective layers 15 be arrayed at equal intervals in the X direction and the Y direction.

A distance d between the protective layers 15 closest to each other in the plurality of protective layers 15 is 10 μm to 100 μm, for example, and is preferably 30 μm to 50 μm. The foregoing distance d is a distance between the parts closest to each other in the protective layers 15 closest to each other. It is preferable that the distance d be small from the viewpoint of increasing the number of subcarriers which can be produced from one wafer. Meanwhile, the distance d is designed to be equal to or larger than a certain size to be larger than the thickness of a cutting blade in order to prevent contact therebetween during cutting blade dicing in a method for manufacturing a subcarrier. In the case of stealth dicing in the method for manufacturing a subcarrier, since cutting lines CL which will become boundary surfaces between chips (subcarriers) lie along laser centers of a laser that is used, it is sufficient for the wafer 10 to be exposed at the laser centers.

For example, side surfaces of the protective layers 15 have a tapered shape, and the distance between adjacent protective layers 15 of the plurality of protective layers 15 increases away from a main surface of the wafer 10, for example. An angle formed between the side surfaces of the protective layers 15 and the main surface S of the wafer 10 is 30° to 90°, for example, and is preferably 40° to 80°. Since the angle formed between the side surfaces of the protective layers 15 and the main surface S of the wafer 10 is an acute angle, a shape in which the distance between adjacent protective layers 15 of the plurality of protective layers 15 increases away from the main surface of the wafer is realized.

For example, a recessed portion C which is recessed compared to a region overlapping the protective layers 15 is formed in a region not overlapping the protective layers 15 in the wafer 10.

The first metal layer 75 and the second metal layer 76 are layers provided between the wafer 10 and an LD 30. The wafer 10 and the LD 30 are connected to each other with the first metal layer 75 and the second metal layer 76 therebetween. A method for forming the first metal layer 75 and the second metal layer 76 is not particularly limited, and any known method can be utilized. Known means such as sputtering, vapor deposition, or pasted metal coating can be utilized. For example, the first metal layer 75 and the second metal layer 76 are constituted using one or a plurality of metals selected from the group consisting of gold (Au), platinum (Pt), silver (Ag), lead (Pb), indium (In), nickel (Ni), titanium (Ti), tantalum (Ta), tungsten (W), an alloy of gold (Au) and tin (Sn), a tin (Sn)-silver (Ag)-copper (Cu)-based solder alloy (SAC), SnCu, InBi, SnPdAg, SnBiIn, and PbBiIn. Each of the first metal layer 75 and the second metal layer is a layer constituted of an arbitrary number of layers (at least one layer), which may include a eutectic metal layer or an electrode layer.

The foregoing embodiment is one embodiment of the present invention and can be suitably changed within the scope of the gist of the claims. For example, an example in which the recessed portion C is formed in a region not overlapping the protective layers 15 in the wafer 10 has been described, but the recessed portion C may not be formed. That is, the main surface S of the wafer 10 may be flat. In addition, shapes of an adhesive layer, an electrode pad 80, and the like are schematically illustrated and can be suitably changed. In addition, for example, an example in which a region between adjacent protective layers 15 on the main surface S of the wafer 10 is the recessed portion C has been described, but the region may have a flat shape.

### [Method for Manufacturing Subcarrier Wafer]

Subsequently, a method for manufacturing the subcarrier wafer 100 according to the foregoing embodiment will be described. The method for manufacturing the subcarrier wafer 100 according to the present embodiment has a surface processing step of etching a wafer having a protective layer formed on a main surface thereof and defining a plurality of protective layers by exposing a part of a region in the wafer.

For example, in the surface processing step, processing is performed by physical etching or chemical etching. In the surface processing step, a region exposing a wafer is a region to be diced in the method for manufacturing a subcarrier which will be described below. From the viewpoint of increasing the number of subcarriers produced from a wafer, it is preferable that the surface processing step be performed such that the regions exposing a wafer form a latticed shape.

In manufacturing a subcarrier wafer, a wafer having a protective layer formed thereon may be used, or the foregoing surface processing step may be performed after a film formation step of forming a protective layer with respect to a wafer is performed. For example, the film formation step is performed by a chemical vapor deposition method.

In the foregoing embodiment, an example in which a part on a surface thereof is exposed by etching the protective layers 15 has been described, but when the method for manufacturing a subcarrier wafer including the film formation step is performed, etching processing can be omitted. When the etching processing is omitted in the method for manufacturing a subcarrier, the method further has a preparation step and a removing step, for example. In this case, the preparation step is a step preceding the film formation step, and an etching mask is formed with respect to a wafer. In addition, a subcarrier wafer having a plurality of protective layers separately formed thereon can be produced by forming a protective layer with respect to a wafer having an etching mask formed thereon in the film formation step, and then removing the mask.

According to the subcarrier wafer and the method for manufacturing the same according to the present embodiment, since the protective layers 15 which may cause chipping, particles, cracking, and the like and are harder than the wafer 10 are partially removed, occurrence of chipping, particles, and cracking is curbed by performing dicing with respect to the region in which the protective layers 15 are removed.

### [Subcarrier]

The subcarrier according to the present embodiment is a subcarrier for a laser module including a base, and the protective layer 15 that is provided on a main surface S of a base 10. A side surface of the protective layer 15 has a tapered shape, and an area of a surface orthogonal to the laminating direction of the protective layer 15 decreases away from the base. The base is a member formed by cutting the wafer 10. The base is defined by the cutting lines CL of the wafer 10.

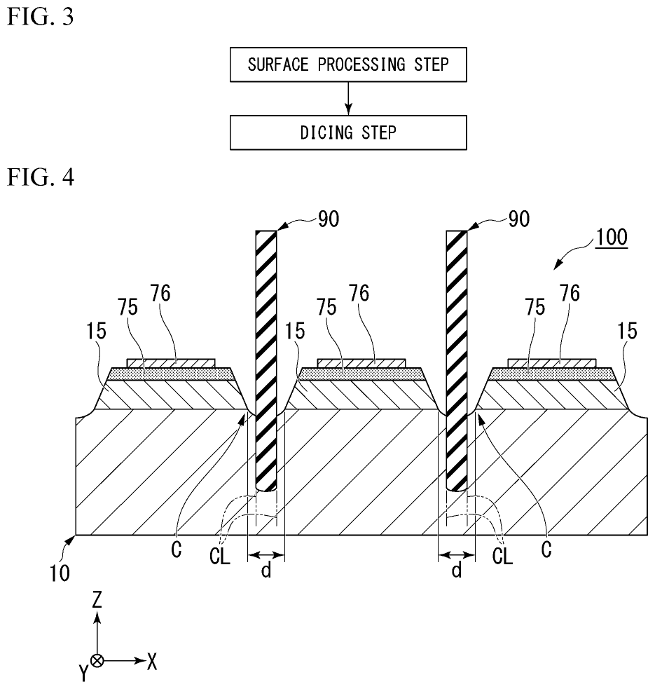

The subcarrier of the present embodiment is produced by dicing a subcarrier wafer. That is, for example, the method for manufacturing a subcarrier of the present embodiment has the foregoing surface processing step, and a dicing step of performing dicing with respect to a region exposing the wafer through the surface processing step. FIG. 3 is a flowchart of the method for manufacturing a subcarrier according to the embodiment of the present invention.

FIG. 4 is an explanatory conceptual view of a form of the dicing step in FIG. 3 and illustrates a condition in which the subcarrier wafer 100 is diced using a cutting blade 90. In FIG. 4, for the sake of description, the cutting lines CL are indicated by two-dot dashed lines.

For example, the dicing step is performed by blade dicing. When the dicing step is performed by blade dicing, in the surface processing step, a plurality of protective layers 15 are defined such that the distance d between the protective layers 15 of the subcarriers becomes larger than the thickness of the cutting blade 90. Next, in the dicing step, the subcarrier wafer 100 is diced using the cutting blade 90.

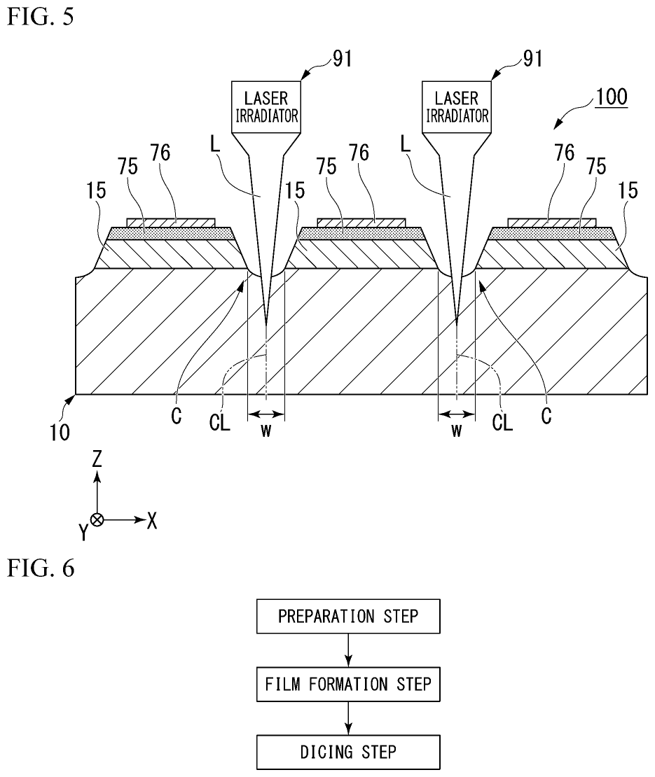

FIG. 5 is an explanatory conceptual view of a form of the dicing step in FIG. 3 and is a view illustrating a modification example in FIG. 4. FIG. 5 illustrates a condition in which the subcarrier wafer 100 is irradiated with a laser L using a laser irradiator 91. The dicing step may be performed by stealth dicing. When the dicing step is performed by stealth dicing, first, the subcarrier wafer 100 is irradiated with the laser L using the laser irradiator 91. Next, the subcarrier wafer 100 is subjected to singulation by applying an external force thereto. The spots irradiated with the laser become the cutting lines CL in the subcarriers. When the dicing step is performed by stealth dicing, if the wafer 10 is exposed at the center of the laser L, occurrence of chipping or cracking during singulation can be curbed.

In FIG. 5, an example in which the laser L does not overlap the protective layers 15 has been described, but if the center of the laser L does not overlap the protective layers 15, a part thereof may overlap the protective layers 15.

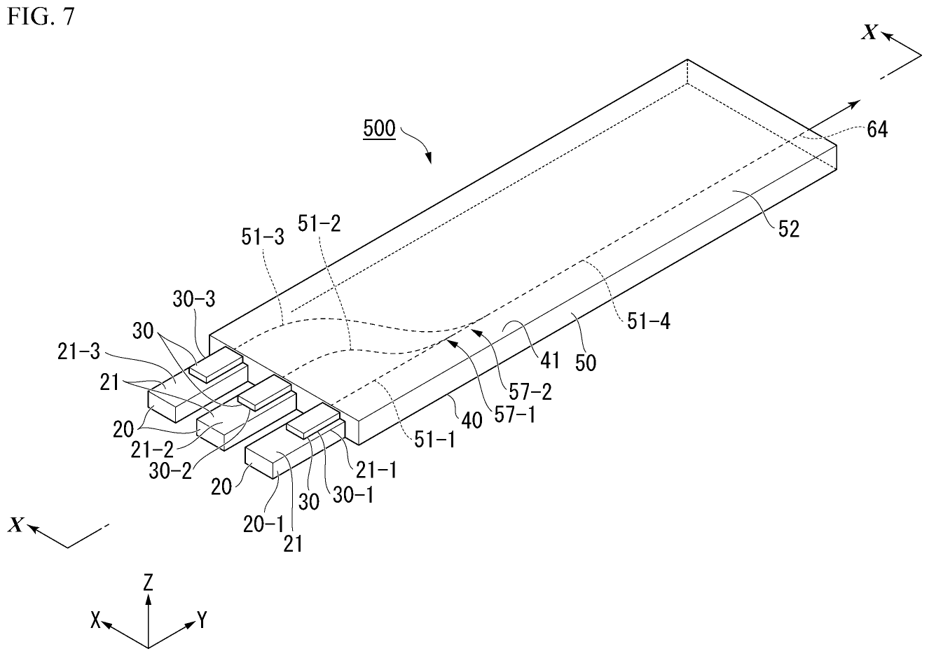

FIG. 6 is a flowchart of the method for manufacturing a subcarrier according to a modification example in FIG. 3. In the method for manufacturing a subcarrier according to the modification example, the surface processing step of etching the wafer 10 having a protective layer formed on the main surface S can be omitted. The method for manufacturing a subcarrier according to the modification example further has a preparation step and a film formation step. The preparation step is a step performed prior to the film formation step, and an etching mask is formed with respect to a wafer. A subcarrier wafer having a plurality of protective layers separately formed thereon can be produced by forming a protective layer with respect to a wafer having an etching mask formed thereon in the film formation step, and then removing the mask. Next, subcarriers can be produced by performing the dicing step and performing dicing with respect to a region exposing the main surface S.

In the method for manufacturing a subcarrier according to the present embodiment, as described above, a plurality of protective layers 15 are separately disposed, and the dicing step is performed such that the cutting lines CL overlap the exposed portions of the wafer 10 exposing a part on the main surface S. For this reason, when the dicing step is performed by blade dicing, contact between the cutting blade 90 and the protective layer 15 can be curbed, and when the dicing step is performed by stealth dicing, a situation in which the laser center overlaps the protective layers 15 can be curbed. Therefore, according to the method for manufacturing a subcarrier of the present embodiment, when blade dicing is performed, contact with the protective layers 15 can be curbed, and occurrence of chipping and particles can be curbed. In addition, when stealth dicing is performed, since the center of the laser L is adjusted such that it does not overlap the protective layers 15, occurrence of cracking and chipping in the protective layers can be curbed during singulation performed by applying an external force thereto.

### [Laser Module]

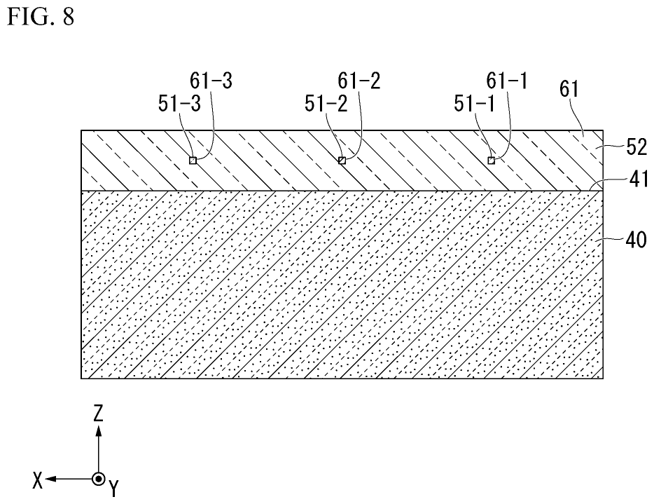

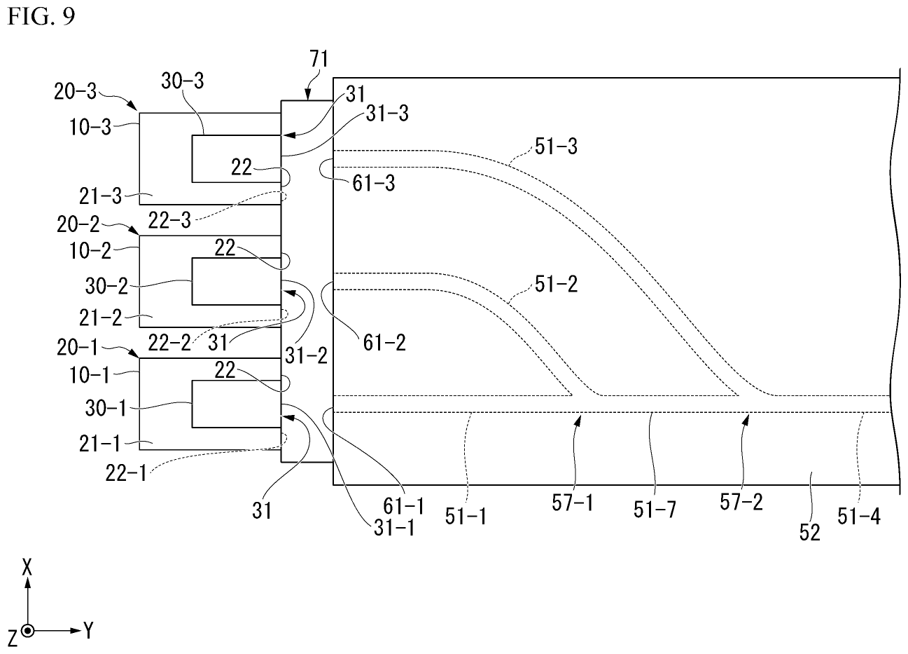

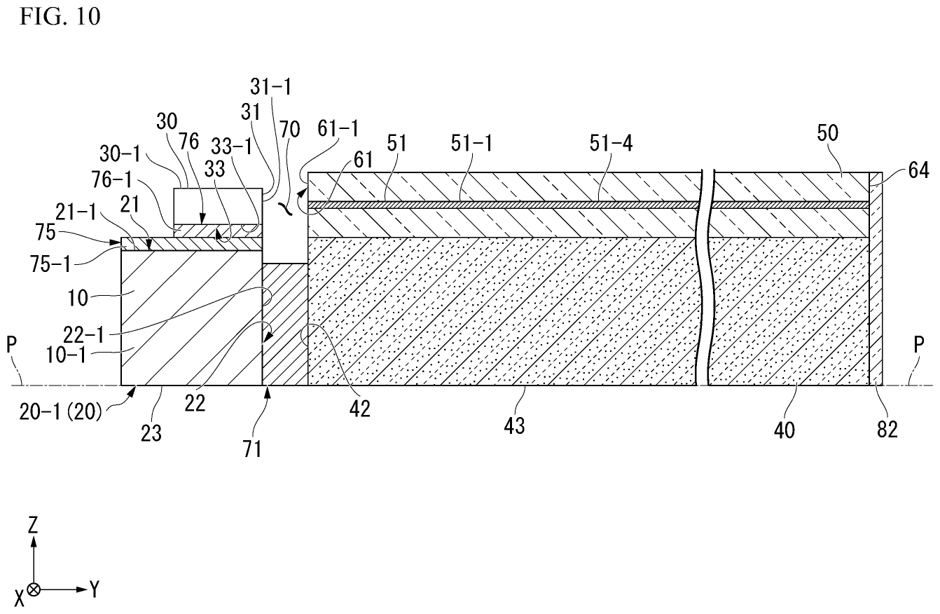

FIG. 7 is a perspective view illustrating an example of a constitution of a laser module according to the embodiment of the present invention. FIG. 8 is a cross-sectional view of an incidence surface of a PLC of the laser module in FIG. 7. FIG. 9 is a plan view of a part of the laser module in FIG. 7. FIG. 10 is a cross-sectional view of the laser module in FIG. 7 along arrow line X-X. In FIGS. 7 to 10, the base 10 having the protective layer 15, the first metal layer 75, and the second metal layer 76 formed thereon will be collectively referred to as subcarriers 20. In addition, in FIGS. 7 to 10, for the sake of description, the first metal layer 75 and the second metal layer 76 may be illustrated separately from the subcarriers 20 and may be omitted. As a member provided in a laser module, a wafer cut in an in-plane direction will be referred to as a base.

A laser module 500 illustrated in FIGS. 7 to 10 includes the subcarriers 20, optical semiconductor elements (LDs) 30 provided on upper surfaces (outer surfaces) 21 of the subcarriers 20, a substrate 40, and an optical waveguide (PLC) 50 provided on an upper surface (outer surface) 41 of the substrate 40.

For example, the laser module 500 is a multiplexer for multiplexing rays of light of colors, such as red (R), green (G), and blue (B) that are three primary colors of light. For example, the laser module 500 can be applied as a multiplexer mounted in a head mounted display. Regarding the LDs 30 (light sources used), various kinds of commercially available laser elements for red light, green light, blue light, and the like can be used. The LDs 30 need only be suitably selected in accordance with the desired purpose. For example, light having a peak wavelength of 610 nm to 750 nm can be used as red light, light having a peak wavelength of 500 nm to 560 nm can be used as green light, and light having a peak wavelength of 435 nm to 480 nm can be used as blue light.

The laser module 500 includes an LD 30-1 emitting red light, an LD 30-2 emitting green light, and an LD 30-3 emitting blue light. The LDs 30-1, 30-2, and 30-3 are disposed with an interval therebetween in a direction substantially orthogonal to an emission direction of light emitted from each of the LDs and are provided on the upper surfaces 21 of the respective subcarriers 20. The LD 30-1 is provided on an upper surface 21-1 of a subcarrier 20-1. The LD 30-2 is provided on an upper surface 21-2 of a subcarrier 20-2. The LD 30-3 is provided on an upper surface 21-3 of a subcarrier 20-3. Hereinafter, regarding the reference sign Z of an arbitrary constituent element of the laser module 500, details common to the constituent elements of the reference signs Z-1, Z-2, and so on to Z-K may be collectively described with the reference sign Z. The sign K described above is a natural number equal to or larger than 2.

Needless to say, light other than red (R), green (G), and blue (B) described in the present embodiment can also be used, and there is no need for a mounting order of red (R), green (G), and blue (B) which have been described using the drawings to be this order and can be suitably changed.

The LDs 30 are mounted on the subcarriers 20 as bare chips. As described above, for example, the subcarriers 20 include the base 10 constituted using Si or the like, and the protective layers 15 formed on the base 10 and constituted using SiOₓ, SiNₓ, a TEOS film, or the like. In the LDs 30, as illustrated in FIG. 10, the first metal layer 75 and the second metal layer 76 are provided between the subcarriers 20 and the LDs 30. The subcarriers 20 and the LDs 30 are connected to each other with the first metal layer 75 and the second metal layer 76 therebetween. The means for forming the first metal layer 75 and the second metal layer 76 is not particularly limited, and any known method can be utilized, that is, sputtering, vapor deposition, pasted metal coating, or the like can be utilized. For example, the first metal layer 75 and the second metal layer 76 are constituted using one or a plurality of metals selected from the group consisting of gold (Au), platinum (Pt), silver (Ag), lead (Pb), indium (In), nickel (Ni), titanium (Ti), tantalum (Ta), tungsten (W), an alloy of gold (Au) and tin (Sn), a tin (Sn)-silver (Ag)-copper (Cu)-based solder alloy (SAC), SnCu, InBi, SnPdAg, SnBiIn, and PbBiIn.

The substrate 40 is constituted using silicon (Si). A PLC 50 is produced on the upper surface 41 such that it is integrated with the substrate 40 by semiconductor processing including known photolithography and dry etching used when fine structures such as integrated circuits are formed. As illustrated in FIGS. 7 and 8, the PLC 50 is provided with a plurality of cores 51-1, 51-2, and 51-3 as many as the LDs 30-1, 30-2, and 30-3, and a cladding 52 surrounding the cores 51-1, 51-2, and 51-3. The thickness of the cladding 52 and the dimensions of the cores 51-1, 51-2, and 51-3 in a width direction are not particularly limited. For example, the cores 51-1, 51-2, and 51-3 having dimensions of approximately several microns in the width direction and having thicknesses smaller than that of the cladding are arranged in the cladding 52 having a thickness of approximately 2 to 50 μm.

For example, the cores 51-1, 51-2, and 51-3 and the cladding 52 are constituted using quartz. The refractive indices of the cores 51-1, 51-2, and 51-3 are higher than the refractive index of the cladding 52 by a predetermined value. Due to this, light incident on each of the cores 51-1, 51-2, and 51-3 propagates through each of the cores while being totally reflected on the boundary surfaces between each of the cores and the cladding 52. For example, the cores 51-1, 51-2, and 51-3 are doped with impurities such as germanium (Ge) in an amount corresponding to the predetermined value described above.

Hereinafter, the emission direction of light emitted from the LDs 30 will be regarded as a y direction. A direction which is orthogonal to the y direction within a plane including the y direction and in which the LDs 30-1, 30-2, and 30-3 are disposed with an interval therebetween will be regarded as an x direction. A direction which is orthogonal to the x direction and the y direction and is directed toward the LDs 30 from the subcarriers 20 will be regarded as a z direction. The x, y, and z directions indicated in FIG. 7 and thereafter do not necessarily correspond to the X, Y, and Z directions in FIGS. 1 and 2. On an incidence surface 61 of the PLC 50, the cores 51-1, 51-2, and 51-3 are disposed along an optical axis of light emitted from the LDs 30-1, 30-2, and 30-3 in the x direction and the z direction.

As illustrated in FIGS. 7 and 9, the cores 51-1, 51-2, and 51-3 are brought together in front of the side reaching an emission surface 64 of the PLC 50. That is, the cores 51-1, 51-2, and 51-3 sequentially approach each other as they go forward in the y direction and merge into one core 51-4. It is preferable that each of the cores 51-1, 51-2, and 51-3 be connected to the core 51-4 with a radius of curvature equal to or larger than a predetermined radius of curvature such that leakage of light from the cores 51-1, 51-2, and 51-3 does not occur.

As illustrated in FIG. 9, the incidence surface 61 of the PLC 50 is disposed in a manner of facing emission surfaces 31 of the LDs 30. Specifically, an emission surface 31-1 of the LD 30-1 faces an incidence surface 61-1 of the core 51-1. In the x direction and the z direction, the optical axis of red light emitted from the LD 30-1 and the center on the incidence surface 61-1 substantially overlap each other. Similarly, an emission surface 31-2 of the LD 30-2 faces an incidence surface 61-2 of the core 51-2. In the x direction and the z direction, the optical axis of green light emitted from the LD 30-2 and the center on the incidence surface 61-2 substantially overlap each other. An emission surface 31-3 of the LD 30-3 faces an incidence surface 61-3 of the core 51-3. In the x direction and the z direction, the optical axis of blue light emitted from the LD 30-3 and the center on the incidence surface 61-3 substantially overlap each other. Due to such a constitution and disposition, at least a part of red light, green light, and blue light emitted from the LDs 30-1, 30-2, and 30-3 can be incident on the cores 51-1, 51-2, and 51-3.

Red light, green light, and blue light emitted from the LDs 30-1, 30-2, and 30-3 are respectively incident on the cores 51-1, 51-2, and 51-3 and then propagate through each of the cores. The cores 51-1 and 51-2 and red light and green light propagating through these cores meet at a predetermined merge position 57-1 (refer to FIG. 9) behind a merge position 57-2 in the y direction. A core 51-7 (refer to FIG. 9) where the cores 51-1 and 51-2 have merged and the core 51-3 and red light, green light, and blue light propagating through these cores meet at the merge position 57-2. Red light, green light, and blue light which have been concentrated at the merge position 57-2 propagate through the core 51-4 and arrive at the emission surface 64. For example, three-color light emitted from the emission surface 64 is used as signal light or the like in accordance with the purpose of use of the laser module 500.

As illustrated in FIG. 10, for example, the subcarriers 20 are connected to the substrate 40 with a bonding film 71 therebetween. For example, a AuSn bonding film or the like is used as the bonding film 71.

An antireflection film (not illustrated) may be provided between the LDs 30 and the PLC 50. For example, an antireflection film is formed integrally with a side surface 42 of the substrate 40 and the incidence surface 61 of the PLC 50. However, an antireflection film 81 may be formed on only the incidence surface 61 of the PLC 50.

In addition to the incidence surface 61, an antireflection film (not illustrated) may also be provided on the emission surface 64. FIG. 7 illustrates a schematic constitution of the laser module 500, and illustration of the bonding film 71 is omitted.

An antireflection film is a film for preventing incident light or emitted light to the PLC 50 from being reflected in a direction opposite to the direction in which it enters each surface from the incidence surface 61 or the emission surface 64 and enhancing the transmittance of incident light or emitted light. For example, an antireflection film is a multilayer film formed by alternately laminating a plurality of kinds of dielectrics with a predetermined thickness corresponding to wavelengths of red light, green light, and blue light (incident light). Examples of the dielectrics described above include titanium oxide (TiO₂), tantalum oxide (Ta₂O₅), silicon oxide (SiO₂), and aluminum oxide (Al₂O₃).

The emission surfaces 31 of the LDs 30 and the incidence surface 61 of the PLC 50 are disposed with a predetermined interval therebetween. The incidence surface 61 faces the emission surfaces 31, and there is a gap 70 between the emission surfaces 31 and the incidence surface 61 in the y direction. Since the laser module 500 is exposed to the air, the gap 70 is filled with air. In consideration of the fact that the laser module 500 is used for a head mounted display, the amount of light required by a head mounted display, and the like, the size of the gap (interval) 70 in the y direction is larger than 0 μm and is equal to or smaller than 5 μm, for example.

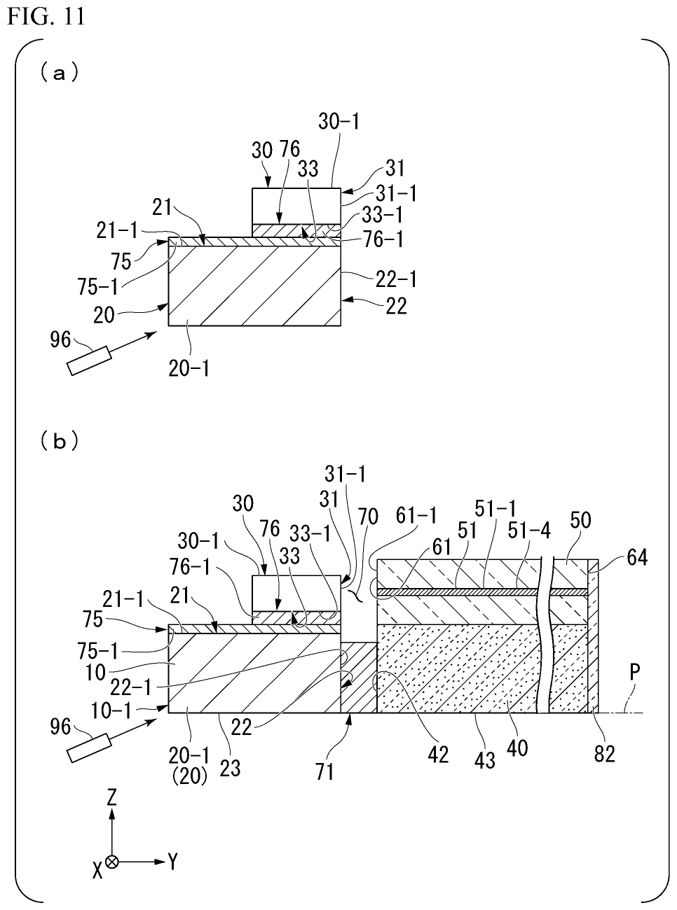

Next, an example of a method for manufacturing the laser module 500 will be simply described. First, the LDs 30 (bare chips) are mounted on the upper surfaces 21 of the subcarriers 20 using a known technique. For example, the first metal layer 75 is formed on the upper surfaces 21 of the subcarriers 20 by means of sputtering, vapor deposition, or the like. Moreover, the second metal layer 76 is formed on lower surfaces 33 of the LDs 30 (for example, a lower surface 33-1 of the LD 30-1) by means of sputtering, vapor deposition, or the like. Next, as illustrated in FIG. 11 (FIG. 11(a)), for example, the subcarriers 20 are irradiated with laser light from a laser 96, and only the subcarriers 20 are heated to the extent that they do not melt and are not deformed. The first metal layer 75 and the second metal layer 76 are softened or melted due to heat transfer from the subcarriers 20, and then they are cooled. Accordingly, the LDs are bonded to the upper surfaces 21 of the subcarriers 20 with the first metal layer 75 and the second metal layer 76 therebetween. In addition, before or after the LDs 30 are mounted on the subcarriers 20, a metal film which becomes eutectic with other metals and forms the bonding film 71 is formed on the side surfaces 22 of the subcarriers 20 by means of sputtering, vapor deposition, or the like.

Next, the PLC 50 is formed on the upper surface 41 of the substrate 40 by known semiconductor processing. Subsequently, a metal film which becomes eutectic with other metals and forms the bonding film 71 is formed behind the substrate 40 in the y direction by sputtering or vapor deposition.

Next, in the x direction and the z direction, the LDs 30, the emission surfaces 31 of the cores 51-1, 51-2, and 51-3, and the incidence surface 61 which correspond to each other are caused to face each other with an interval therebetween in the y direction. The optical axis of each ray of color light emitted from the LD 30 and the center of the incidence surface 61 of the corresponding core are caused to substantially overlap each other. At this time, for example, the bottom surfaces 23 of the subcarriers 20 and the bottom surface 43 of the substrate 40 may be disposed in an aligned manner such that bottom surfaces 23 of the subcarriers 20 and a bottom surface 43 of the substrate 40 are substantially on the same plane.

Next, as illustrated in FIG. 11 (FIG. 11(b)), the subcarriers 20 are irradiated with laser light from the laser 96, and a metal layer formed between the subcarriers 20 and the substrate 40 is softened or melted due to heat transfer from the subcarriers 20. Relative positions of the LDs 30 and the PLC 50 are adjusted, and the subcarriers 20 having the LDs 30 mounted thereon are bonded to the substrate 40 having the PLC 50 formed thereon. Through such steps, the laser module 500 can be manufactured.

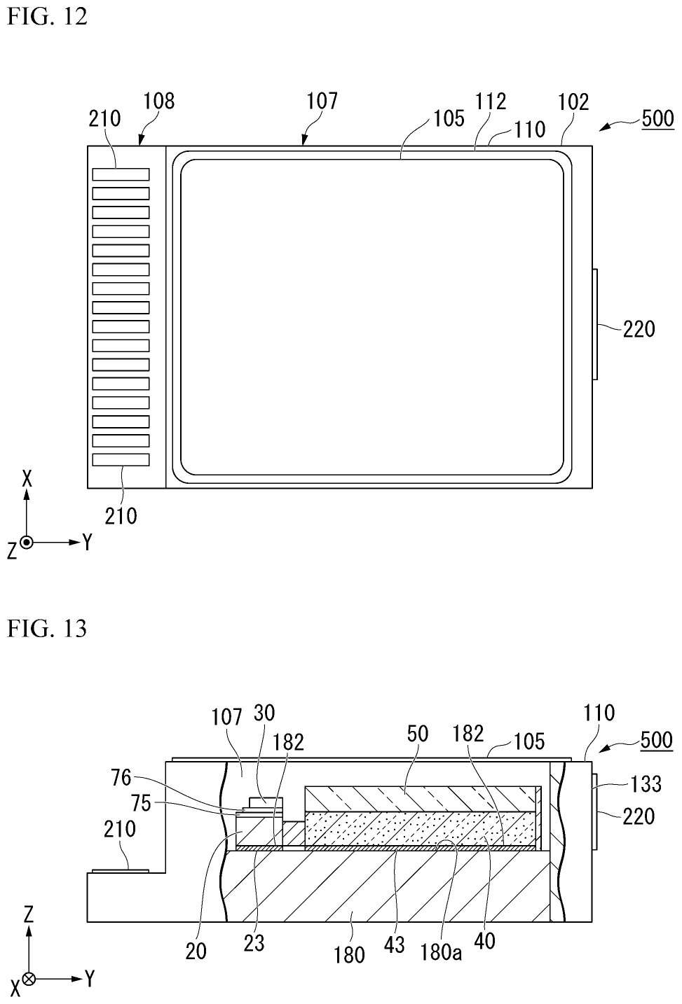

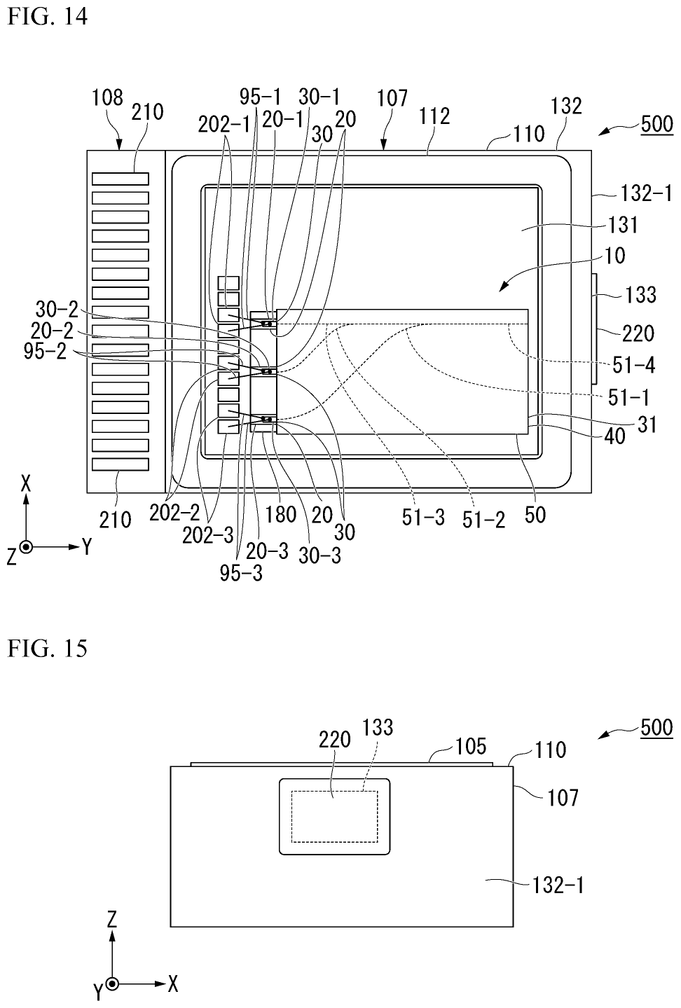

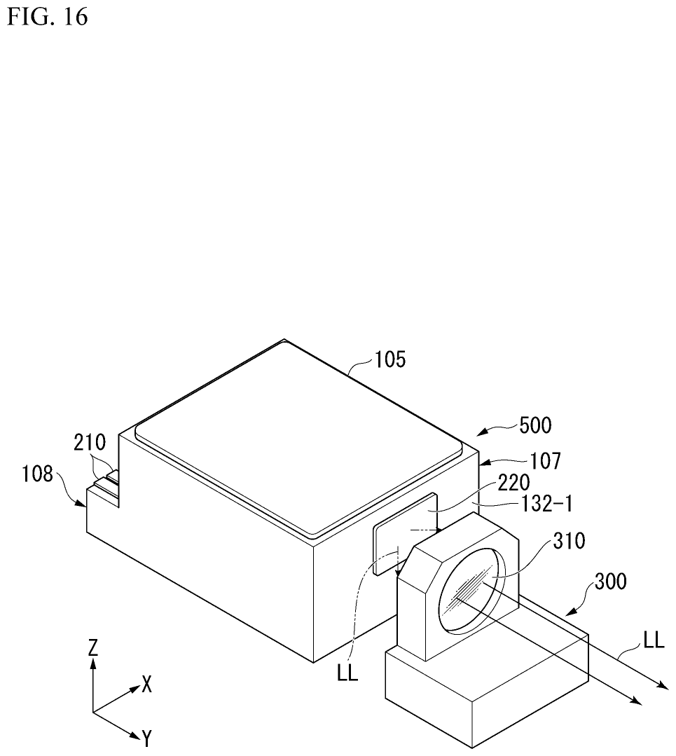

The laser module according to the embodiment of the present invention may be accommodated in a package 110 as illustrated in FIGS. 12 to 16. FIG. 12 is a plan view of a packaged laser module. FIG. 13 is a cross-sectional view of the laser module in FIG. 12, FIG. 14 is a plan view of a state in which a cover of the laser module in FIG. 12 is removed, FIG. 15 is a side view of the laser module in FIG. 12 viewed from an emission portion side, and FIG. 16 is a perspective view illustrating a form when the laser module in FIG. 12 is in use. In a laser module 500A illustrated in FIGS. 12 to 16, the laser module 500 is accommodated in the package 110. The package 110 includes a main body 102 having a cavity structure, and a cover 105 covering the main body 102.

The main body 102 includes a box-shaped accommodation portion 107 accommodating the laser module 500, and an electrode portion 108 adjacent to the accommodation portion 107. For example, the main body 102 is formed of ceramic or the like. An opening is formed on an upper surface of the accommodation portion 107. A metal film 112 of Kovar or the like is formed on the upper surface of the accommodation portion 107 of a circumferential edge of the opening in a top view. The cover 105 tightly covers the opening formed on the upper surface of the accommodation portion 107 with the metal film 112 therebetween. When the accommodation portion 107 is airtightly sealed with the cover 105, the accommodation portion 107 is airtightly sealed by the cover 105. An internal space of the accommodation portion 107 is filled with inert gas. Accordingly, the gap 70 (refer to FIG. 11 (FIG. 11(b))) is filled with inert gas.

As illustrated in the diagrams, for example, a substructure 180 for installing the laser module 500 is provided at a predetermined position of a bottom wall portion 131 of the accommodation portion 107. The laser module 500 is provided on the substructure 180. That is, the laser module 500 is disposed in the internal space of the accommodation portion 107. In the laser module 500, the bottom surfaces 23 of the subcarriers 20 and the bottom surface (substrate bottom surface) 43 of the substrate 40 may be formed substantially on the same plane P. Here, being substantially on the same plane P allows slight deviation between the bottom surface 23 and the bottom surface (substrate bottom surface) 43. Specifically, deviation within a range of 20 μm or smaller with respect to the thickness of the substrate 40 in the z direction is allowed. In addition, the bottom surfaces 23 of the subcarriers 20 and the bottom surface (substrate bottom surface) 43 of the substrate 40 may be bonded to each other between an upper surface 180a (one inner surface) of the substructure 180 with an adhesive layer 182 therebetween.

For example, the adhesive layer 182 is constituted using a resin into which a filler is mixed. An epoxy resin or the like is used as a resin, and a silver powder or the like is used as a filler. In addition, the adhesive layer 182 preferably has a thermal conductivity of 0.5 W/m·K or higher in order to maintain thermal conduction at a certain level or higher.

Due to such a constitution, heat generated through operation of the LDs 30 can be efficiently dissipated toward the substructure 180 from both the bottom surfaces 23 of the subcarriers 20 and the bottom surface (substrate bottom surface) 43 of the substrate 40. In addition, both the bottom surfaces 23 of the subcarriers 20 and the bottom surface (substrate bottom surface) 43 of the substrate 40 may be bonded to each other using an adhesive layer constituted using a resin into which a filler is mixed.

A plurality of internal electrode pads 202 are provided in the bottom wall portion 131 at positions between the substructure 180 below the subcarriers 20 and external electrode pads 210 in the y direction with an interval therebetween in the x direction.

Each of the LDs 30 and the subcarriers 20 and the internal electrode pads 202 of the plurality of internal electrode pads 202 corresponding to the respective LDs 30 are connected to each other using a wire 95 by a method such as wire bonding. For example, each of the LD 30-1 and the subcarrier 20-1 and each of two internal electrode pads 202-1 are individually connected to each other using a wire 95-1. Each of the LD 30-2 and the subcarrier 20-2 and each of two internal electrode pads 202-2 are individually connected to each other using a wire 95-2. Each of the LD 30-3 and the subcarrier 20-3 and each of two internal electrode pads 202-3 are individually connected to each other using a wire 95-3.

The respective internal electrode pads 202-1, 202-2, and 202-3 is connected to the external electrode pads 210 different from each other. As described above, the external electrode pads 210 electrically connected to the respective internal electrode pads 202-1, 202-2, and 202-3 are electrically connected to a power source (not illustrated) or the like. That is, in the laser module 500A, the LDs 30 and the power source (not illustrated) are connected to each other by the wire 95, the internal electrode pads 202-1, 202-2, and 202-3, and the external electrode pads 210. When power is supplied from the power source (not illustrated) to the external electrode pads 210 corresponding to the respective internal electrode pads 202-1, 202-2, and 202-3, red light, green light, and blue light are emitted from the LDs 30-1, 30-2, and 30-3.

In the laser module 500A, an opening 133 is formed in a side wall portion 132 of the laser module 500 facing the emission surface 31 of the PLC 50 in the side wall portion 132 of the accommodation portion 107. The opening 133 is formed on the surface of the side wall portion 132 to be larger than the size of three-color light which is emitted from the core 51-4 of the PLC 50 in the side wall portion 132 and diffuses in the internal space of the accommodation portion 107. As illustrated in FIGS. 14 and 15, the opening 133 is airtightly sealed from the outside of the side wall portion 132 by a glass plate 220. An antireflection film (not illustrated) is provided on both plate surfaces of the glass plate 220.

The opening 133 is a window through which three-color light emitted from the core 51-4 of the PLC 50 passes and propagates to the outside of the package 110. As illustrated in FIG. 16, three-color light LL emitted from the core 51-4 of the PLC 50 passes through the opening 133 and the glass plate 220 while diffusing centrically in the y direction and travels toward a deep side of the package 110 in the y direction, that is, forward in the y direction. For example, a collimator 300 including a collimating lens 310 can be disposed on the deep side of the package 110 in the y direction from a side wall portion 132-1. The three-color light LL emitted from the core 51-4 is collimated and becomes parallel light by aligning a distance between the emission surface 31 and the collimating lens 310 in the y direction with a focal distance of the collimating lens 310 and aligning the center of the collimating lens 310 on the optical axis of the three-color light LL.

### [XR Glasses] [Optical Engine Module]

In XR glasses according to the present embodiment, any laser module according to the foregoing embodiment is mounted in the glasses. The XR glasses (eyeglasses) are an eyeglass-type terminal, and XR is a general term of virtual reality (VR), augmented reality (AR), and mixed reality.

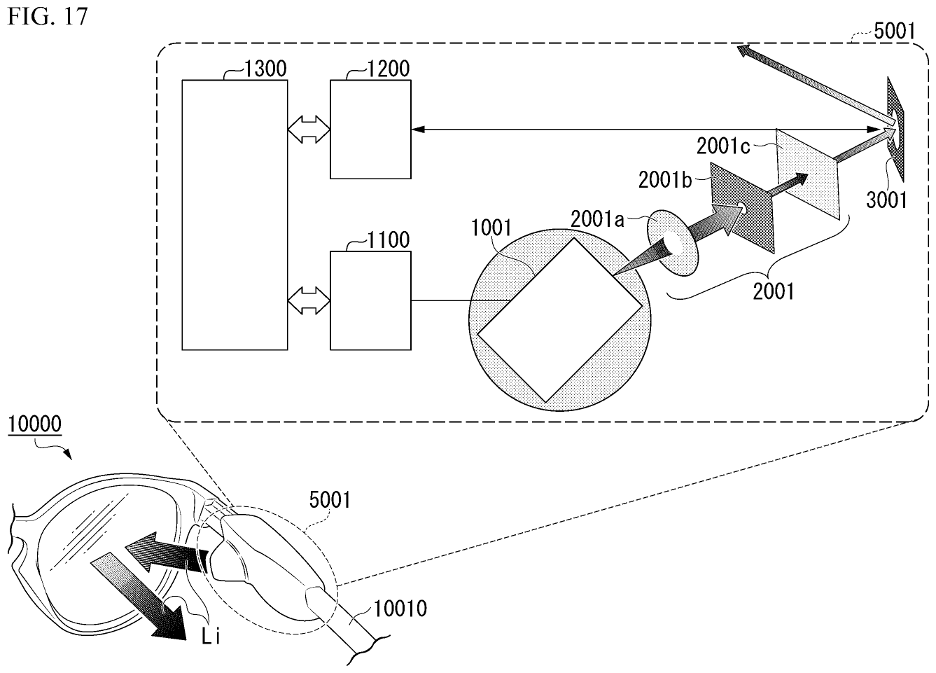

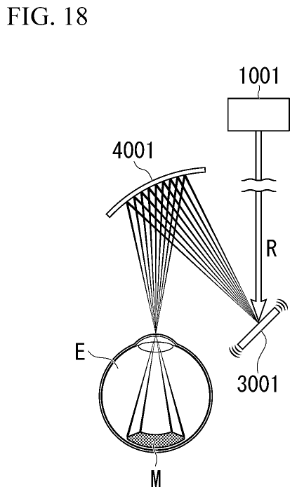

FIG. 17 is an explanatory conceptual view of XR glasses according to the embodiment of the present invention. In XR glasses 10000 illustrated in FIG. 17, a laser module 1001 is mounted in a frame 10010. The reference sign Li in FIG. 17 indicates image display light. In addition, FIG. 18 is a conceptual view illustrating a condition in which an image is directly projected onto the retina by laser light emitted from the laser module according to the embodiment of the present invention.

In the present embodiment, the laser module 1001, an optical scanning mirror 3001, and an optical system 2001 connecting the laser module 1001 and the optical scanning mirror 3001 to each other will be collectively referred to as an optical engine module 5001 (illustrated in FIG. 17). The laser module according to the foregoing embodiment can be used as the laser module 1001.

For example, a light source having RGB laser light sources including a red laser light source 60-1, a green laser light source 60-2, and a blue laser light source 60-3, and a near-infrared laser light source can be used as the light source of the laser module 1001.

As illustrated in FIG. 18, a laser R for irradiation from the laser module 1001 attached to the eyeglass frame is reflected by the optical scanning mirror 3001. The reflected light is reflected by a mirror 4001 reflecting light in a direction of the eyeball E of a human and enters the inside of the eyeball E of the human so that an image (video image) can be directly projected onto the retina M.

The optical engine module includes an eye-tracking mechanism so that an image is directly projected onto the retina while eye-tracking is performed. A known mechanism can be used as the eye-tracking mechanism.

For example, the optical scanning mirror 3001 is a MEMS mirror. In order to project a 2D image, it is preferable that the optical scanning mirror 3001 be a 2-axis MEMS mirror which oscillates such that laser light is reflected while varying the angle in the horizontal direction (X direction) and the vertical direction (Y direction).

For example, the optical engine module includes a collimator lens 2001a, a slit 2001b, and an ND filter 2001c as the optical system 2001 for optically processing laser light emitted from the laser module 1001. The foregoing optical system is an example, and the optical system 2001 may have a different constitution.

The optical engine module 5001 includes a laser driver 1100, an optical scanning mirror driver 1200, and a video controller 1300 controlling these drivers.

While preferred embodiments of the invention have been described and illustrated above, it should be understood that these are exemplary examples of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### APPENDIX

(a) A laser module according to another aspect of the present disclosure includes the subcarrier according to the aspects described in (1)-(6) above.
(b) An optical engine module according to another aspect of the present disclosure includes the laser module according to the foregoing aspect, and an optical scanning mirror that performs scanning with light emitted from the laser module.
(c) XR glasses according to another aspect of the present disclosure include the optical engine module according to the foregoing aspect.
(d) A method for manufacturing a subcarrier according to another aspect of the present disclosure has a surface processing step of etching a wafer having a protective layer formed on a main surface thereof and defining a plurality of protective layers by exposing a part of a region in the wafer, and a dicing step of performing dicing with respect to a region exposing the wafer through the surface processing step.

### EXPLANATION OF REFERENCES

10 Wafer
15 Protective layer
20, 20-1, 20-2, 20-3 Subcarrier
21, 21-1, 21-2, 21-3 Upper surface
22, 22-1, 22-2, 22-3 Side surface (first side surface)
23 Bottom surface
30 Laser diode (LD)
31, 31-1, 31-2, 31-3 Emission surface
33 Lower surface
40 Substrate
41 Upper surface
42 Side surface
43 Bottom surface (substrate bottom surface)
51-1, 51-2, 51-3 Core
52 Cladding
60-1 Red laser light source
60-2 Green laser light source
60-3 Blue laser light source
61, 61-1, 61-2, 61-3 Incidence surface
64 Emission surface
70 Gap (interval)
75 First metal layer
76 Second metal layer
81, 82 Antireflection film
90 Cutting blade
91 Laser irradiator
100 Subcarrier wafer
102 Main body
105 Cover
107 Accommodation portion
108 Electrode portion
110 Package
112 Metal film
131 Bottom wall portion
132 Side wall portion
133 Opening
180 Substructure
180a Upper surface
182 Adhesive layer
202 External electrode pad
220 Glass plate
300 Collimator
310 Collimating lens
500, 500A, 1001 Laser module
1100 Laser driver
1200 Optical scanning mirror driver
1300 Video controller
2001 Optical system
2001a Collimator lens
2001b Slit
2001c ND filter
3001 Optical scanning mirror
4001 Mirror
5001 Optical engine module
10000 XR glasses
10010 Frame
C Recessed portion
CL Cutting line
D Distance
E Eyeball
L Laser
M Retina

What is claimed is:

1. A subcarrier wafer for a laser module comprising:
a wafer; and
a plurality of protective layers that are provided on a main surface of the wafer,
wherein the plurality of protective layers are arrayed separately, and
a part on the main surface of the wafer is exposed.

2. The subcarrier wafer according to claim 1,
wherein side surfaces of the protective layers have a tapered shape, and
a distance between adjacent protective layers of the plurality of protective layers increases away from the main surface of the wafer.

3. The subcarrier wafer according to claim 1,
wherein a recessed portion which is recessed compared to a region overlapping the protective layers is formed in a region not overlapping the protective layers in the wafer.

4. The subcarrier wafer according to claim 1,
wherein the wafer includes Si as a main component, and
the protective layers include one selected from the group consisting of Si oxide, Si nitride, and a TEOS film as a main component.

5. The subcarrier wafer according to claim 1,
wherein a distance between adjacent protective layers of the plurality of protective layers is 10 μm or longer.

6. A subcarrier for a laser module comprising:
a base; and
a protective layer that is provided on a main surface of the base,
wherein a side surface of the protective layer has a tapered shape, and
an area of the protective layer in a planar view decreases away from the base.

7. A method for manufacturing a subcarrier wafer comprising:
a surface processing step of etching a wafer having a protective layer formed on a main surface thereof and defining a plurality of protective layers by exposing a part of a region in the wafer.
